(19) United States
(12) Patent Application Publication
(10) Pub. No.: US 2007/0080392 A1
(43) Pub. Date: Apr. 12, 2007

(54) SEMICONDUCTOR DEVICE AND METHOD OF FABRICATING THE SAME

(75) Inventor: Kanna TOMIYE, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/535,706

(22) Filed: Sep. 27, 2006

(30) Foreign Application Priority Data
Sep. 30, 2005 (JP) 2005-288218

(51) Int. Cl. H01L 29/788; H01L 21/336

(52) U.S. Cl. 257/315; 438/300

(57) ABSTRACT

A semiconductor device according to one embodiment of the present invention includes: a semiconductor substrate; a gate electrode formed on the semiconductor substrate through a gate insulating film; an elevated source/drain region formed away from the gate electrode, a surface of the elevated source/drain region being higher than that of the semiconductor substrate; a source/drain extension region formed in the semiconductor substrate lying under a recess portion formed between the gate electrode and the elevated source/drain region; a first gate sidewall insulating film formed on a side face of the gate electrode, and on a bottom face and a side face of the recess portion; and a second gate sidewall insulating film formed on the first gate sidewall insulating film.

### CROSS-REFERENCE TO RELATED APPLICATION

This application is based upon and claims the benefit of priority from prior Japanese Patent Application No. 2005-288218, filed Sep. 30, 2005, the entire contents of which are incorporated herein by reference.

### BACKGROUND OF THE INVENTION

The present invention relates to a semiconductor device having an elevated source/drain structure and a method of fabricating the same.

In recent years, parasitic capacitances have become more remarkable in accordance with miniaturization of semiconductor devices. An increase in parasitic capacitance exerts the various bad influences on the semiconductor device. For example, in a metal oxide semiconductor field-effect transistor (MOSFET), a parasitic capacitance occurring between a gate electrode and a source/drain region reduces an operation speed of the MOSFET.

In the transistor having a gate electrode coated with a gate sidewall insulating film formed of an insulating material, the parasitic capacitance occurs due to the gate sidewall insulating film. Since a material having a low relative dielectric constant must be used as the insulating material in order to reduce the parasitic capacitance, SiO₂ having a relatively low relative dielectric constant is used as the material for the gate sidewall insulating film in many cases.

However, when silicon or the like is epitaxially grown on a silicon substrate to form thereon an elevated source/drain structure, or when a metal film is formed by utilizing a sputtering method and is then subjected to a heat treatment, thereby forming silicide regions in the vicinities of surfaces of a gate electrode and a source/drain region, respectively, an oxide film formed on a surface of a portion to be processed must be removed by using a hydrofluoric acid or the like as a pretreatment of these processes. Thus, when SiO₂ is used as the material for the sidewall, it is etched away during this pretreatment. In addition, if SiO₂ exists on the surface of the gate sidewall insulating film when the remaining metal after formation of the silicide region is removed, the remaining metal cannot be removed and is left in some cases. Furthermore, when the surface of the gate sidewall insulating film is made of SiO₂, the gate sidewall insulating film is etched by the etching in the phase of formation of a contact in some cases.

Then, although there is utilized a technique using Si₃N₄ showing a high etching selectivity to an oxide film or silicon as the material for the sidewall, since Si₃N₄ has a higher relative dielectric constant than that of SiO₂, the parasitic capacitance occurring therein becomes large.

On the other hand, there is reported a technique for reducing a parasitic capacitance by using a gate sidewall insulating film having a multi-layer structure including a layer made of a material, such as Si₃N₄, having a relatively high relative dielectric constant, and a layer made of a material having a relatively low relative dielectric constant. This technique, for example, is disclosed in Japanese Patent KOKAI No. 2004-6891.

When the technique for forming the gate sidewall insulating film in the form of the multi-layer structure is used, a material such as SiO₂ having a relatively low relative dielectric constant can be used for the lower layer of the gate sidewall insulating film to reduce the parasitic capacitance, and a material, such as Si₃N₄, showing a high etching selectivity to the oxide film can be used for the upper layer thereof to suppress etching damage in the pretreatment. In spite of this, according to the fabricating method in the prior art, in the case of the transistor having the elevated source/drain structure, there is encountered such a problem that it is impossible to effectively reduce the parasitic capacitance because the material, such as Si₃N₄, having the high relative dielectric constant contacts the elevated source/drain region.

### BRIEF SUMMARY OF THE INVENTION

A semiconductor device according to one embodiment of the present invention includes:

a semiconductor substrate;

a gate electrode formed on the semiconductor substrate through a gate insulating film;

an elevated source/drain region formed away from the gate electrode, a surface of the elevated source/drain region being higher than that of the semiconductor substrate;

a source/drain extension region formed in the semiconductor substrate lying under a recess portion formed between the gate electrode and the elevated source/drain region;

a first gate sidewall insulating film formed on a side face of the gate electrode, and on a bottom face and a side face of the recess portion; and

a second gate sidewall insulating film formed on the first gate sidewall insulating film.

A method of fabricating a semiconductor device according to another embodiment of the present invention includes:

forming a gate electrode and a dummy gate sidewall insulating film above a semiconductor substrate;

forming an elevated source/drain region comprising silicon or a silicon compound in an exposed area of a surface of the semiconductor substrate after forming the gate electrode and the dummy gate sidewall insulating film above the semiconductor substrate;

removing the dummy gate sidewall insulating film; and

forming a plurality of insulating films comprising two or more different kinds of materials on the semiconductor substrate, and patterning the plurality of insulating films to form a gate sidewall insulating film comprising a multiple layer structure in a portion where the dummy gate sidewall insulating film has been removed.

### BRIEF DESCRIPTION OF THE DRAWINGS

FIGS. 1A to 1L are respectively cross sectional views showing processes for fabricating a semiconductor device according to a first embodiment of the present invention; and

FIGS. 2A to 2D are respectively cross sectional views showing processes for fabricating a semiconductor device according to a second embodiment of the present invention.

### DETAILED DESCRIPTION OF THE INVENTION

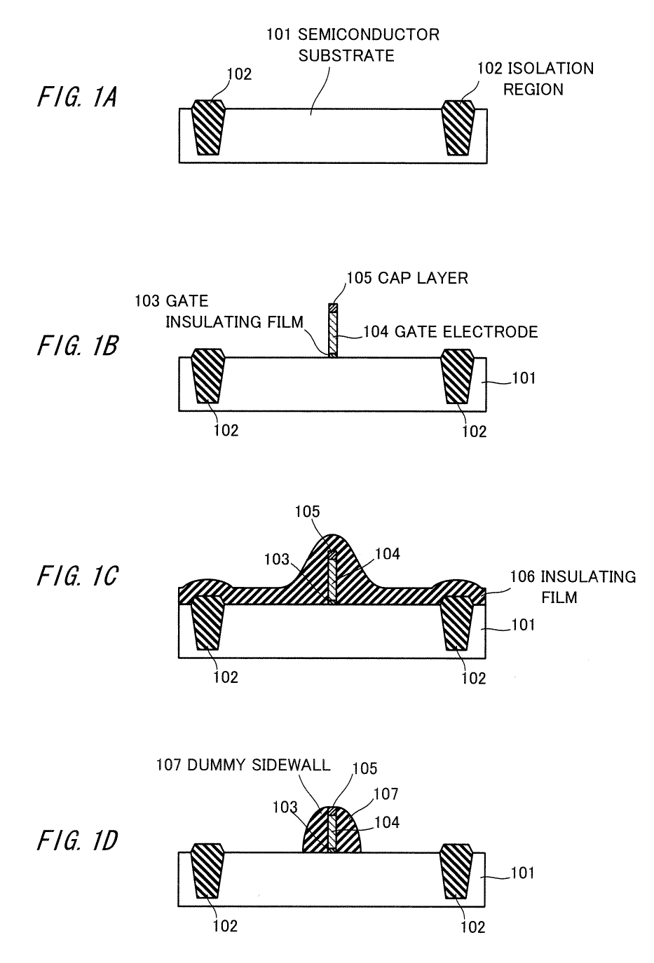

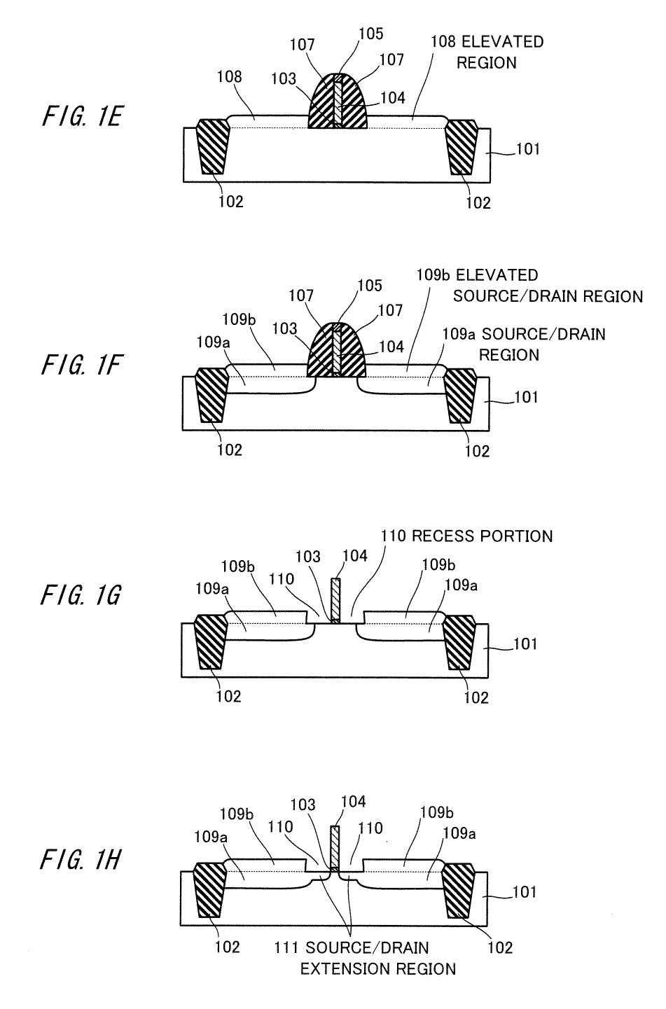

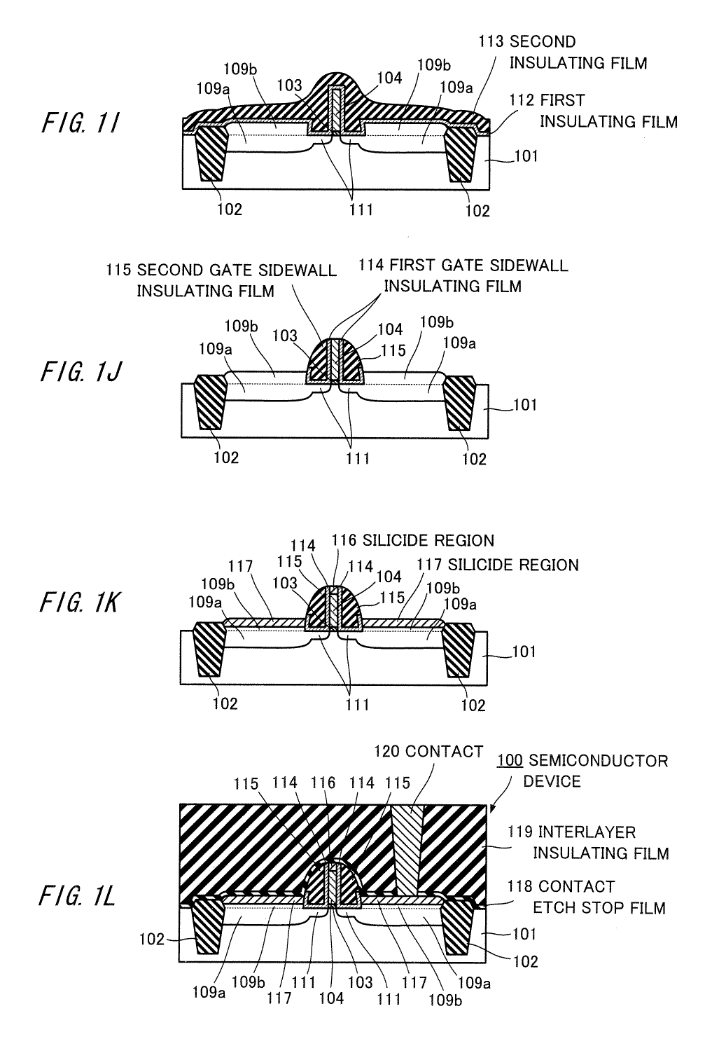

FIGS. 1A to 1L are respectively cross sectional views showing processes for fabricating a semiconductor device according to a first embodiment of the present invention.

Firstly, as shown in FIG. 1A, an isolation region 102 which, for example, has shallow trench isolation (STI) structure is formed in a semiconductor substrate 101. Channel doping, formation of a well, and the like are carried out by utilizing an ion implantation method and activation anneal is then performed for them when necessary. Here, a bulk silicon substrate or a silicon on insulator (SOI) substrate can be used as the semiconductor substrate 101.

Next, a gate insulating film material such as SiON or SiO₂, and a gate electrode material such as polycrystalline silicon or polycrystalline silicon germanium are successively formed over the whole surface on the semiconductor substrate 101. Then, ions of As, P or the like in the case of an N-channel MOSFET, and ions of B, BF₂ or the like in the case of a P-channel MOSFET are implanted as impurity ions into the gate electrode material by utilizing an ion implantation method, and the gate electrode material is then subjected to activation anneal. Moreover, after a cap layer material formed of, for example, an Si₃N₄ film is formed on the gate electrode material, the gate insulating film material, the gate electrode material, and the cap layer material are patterned through a photo resist process, a reactive ion etching (RIE) process and the like. As a result, as shown in FIG. 1B, a gate insulating film 103, a gate electrode 104, and a cap layer 105 are formed.

Next, as shown in FIG. 1C, an insulating film 106 made of a material, such as Si₃N₄, showing a high etching selectivity to an oxide film is deposited over the whole surface of the semiconductor substrate 101. The insulating film 106 may be made of a material with which a certain etching selectivity to silicon is obtained.

Next, as shown in FIG. 1D, the insulating film 106 is patterned through the RIE process to form a dummy sidewall 107. Note that, the dummy sidewall 107 may not have a single layer structure, but may have a multi-layer structure. In this case, a surface of the dummy sidewall 107 is desirably made of a material showing a high etching selectivity to an oxide film.

Next, after a pretreatment for removing an oxide film is performed for an area through which the surface of the semiconductor substrate 101 is exposed, as shown in FIG. 1E, silicon or a silicon compound such as silicon germanium is selectively and epitaxially grown on that area to form an elevated region 108. At this time, no gate electrode 104 is grown due to existence of the cap layer 105. Here, a height of the elevated region 108 thus grown, for example, is on the order of 25 to 30 nm. Note that, when the surface of the dummy sidewall 107 is made of Si₃N₄, there is also an advantage such that a facet hardly occurs.

Next, as shown in FIG. 1F, ions of As, P or the like in the case of the N-channel MOSFET, and ions of B, BF₂ or the like in the case of the P-channel MOSFET are implanted as impurity ions into the elevated region 108 by utilizing the ion implantation method, and the elevated region 108 is then subjected to the activation anneal, thereby forming a source/drain region 109a and an elevated source/drain region 109b.

Next, as shown in FIG. IG, the cap layer 105 and the dummy sidewall 107 are both peeled off. Here, a recess portion 110 is generated in a portion (defined between the gate electrode 104 and the elevated source/drain region 109b), on the semiconductor substrate 101, from which the dummy sidewall 107 has been removed.

Next, as shown in FIG. 1H, ions of As, P or the like in the case of the N-channel MOSFET, and ions of B, BF₂ or the like in the case of the P-channel MOSFET are implanted as impurity ions into a portion, of the semiconductor substrate 101, lying under the recess portion 110 by utilizing the ion implantation method, and the activation anneal is then carried out, thereby forming a source/drain extension region 111.

Next, as shown in FIG. 1I, a first insulating film 112 made of, for example, SiO₂, and a second insulating film 113 made of a material, such as Si₃N₄, showing a high etching selectivity to an oxide film or silicon are successively deposited over the whole surface of the semiconductor substrate 101. Here, the first insulating film 112 is preferably made of a material having a lower relative dielectric constant than that of the second insulating film 113, and its thickness, for example, is about 5 nm. Note that, a film deposition temperature at this time is not higher than 600° C.

Next, as shown in FIG. 1J, the first insulating film 112 and the second insulating film 113 are patterned through the RIE process. As a result, a first gate sidewall insulating film 114 is formed on a side face of the gate electrode 104, and on a bottom face and a side face of the recess portion 110, and also a second gate sidewall insulating film 115 is formed on the first sidewall insulating film 114.

Next, after the pretreatment for removing an oxide film is performed for the whole surface on the semiconductor substrate 101, a metal film made of any one of Ni, Pt, Co, Pd, Er or NiPt is deposited by utilizing a sputtering method, and the anneal is then performed. As a result, a salicide reaction occurs, so that silicide regions 116 and 117 are formed in the vicinities of the surfaces of the gate electrode 104 and the elevated source/drain region 109b, respectively. After that, as shown in FIG. 1K, the remaining unreacted metal film is removed. Note that, the silicide region 116 of the gate electrode 104 may not occupy a part of the gate electrode 104, but may occupy all the gate electrode 104 (Fully Silicided Gate).

Next, a contact etch stop film 118 made of, for example, Si₃N₄, and an interlayer insulating film 119 made of, for example, SiO₂ are successively deposited over the whole surface on the semiconductor substrate 101, and a surface of the interlayer insulating film 119 is then flattened by utilizing a chemical mechanical polish (CMP) method or the like. Thereafter, the contact etch stop layer 118 and the interlayer insulating film 119 are patterned to form a contact hole, and a metal such as W is then sputtered. As a result, there is obtained a semiconductor device 100, as shown in FIG. 1L, having the contact 120, a wiring layer (not shown) and the like.

According to the first embodiment of the present invention, a volume ratio of the first gate sidewall insulating film 114 to the second gate sidewall insulating film 115 is increased in the gate sidewall insulating films existing between the gate electrode 104 and the elevated source/drain region 109b. As a result, it is possible to suppress a parasitic capacitance.

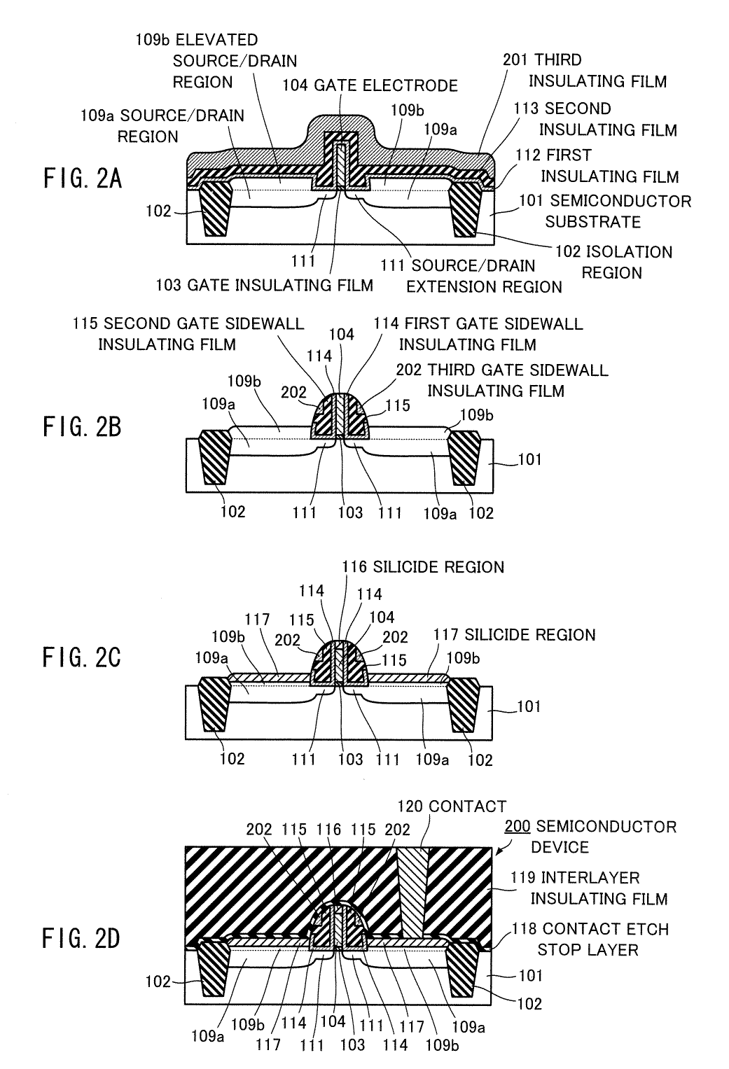

In addition, since the second gate sidewall insulating film 115 having the high relative dielectric constant does not contact the elevated source/drain region 109b due to the existence of the first gate sidewall insulating film 114, it is possible to suppress a parasitic capacitance. FIGS. 2A to 2D are respectively cross sectional views showing processes for fabricating a semiconductor device according to a second embodiment of the present invention. Note that, since the processes for fabricating a semiconductor device according to the second embodiment are the same as those until the process shown in FIG. 1H of the first embodiment, their descriptions are omitted here for the sake of simplicity.

After completion of the process shown in FIG. 1H, as shown in FIG. 2A, a first insulating film 112 made of, for example, SiO₂, a second insulating film 113 made of, for example, Si₃N₄, showing a high etching selectivity to an oxide film, and a third insulating film 201 made of, for example, SiO₂ are successively deposited over the whole surface on the semiconductor substrate 101. Here, the first insulating film 112 and the third insulating film 201 are preferably respectively made of materials each having a lower relative dielectric constant than that of the second insulating film 113. The first insulating film 112 and the third insulating film 201 may be made of the same material, or may be made of different materials. Note that, the film deposition temperature at this time is not higher than 600° C.

Next, as shown in FIG. 2B, the first insulating film 112, the second insulating film 113 and the third insulating film 201 are patterned by utilizing the RIE process. As a result, a first gate sidewall insulating film 114 is formed on a side face of the gate electrode 104, and on a bottom face and a side face of the recess portion 110, and a second gate sidewall insulating film 115 is formed on the first sidewall insulating film 114. Moreover, a third gate sidewall insulating film 202 is formed on a surface of a part of the second gate sidewall insulating film 115. The third gate sidewall insulating film 202 is formed in a higher position than that of the surface of the elevated source/drain region 109b.

Next, after the pretreatment for removing an oxide film is performed for the whole surface on the semiconductor substrate 101, a metal film made of any one of Ni, Pt, Co, Pd, Er or NiPt is deposited by utilizing the sputtering method, and the anneal is then performed. As a result, the salicide reaction occurs, so that silicide regions 116 and 117 are formed in the vicinities of the surfaces of the gate electrode 104 and the elevated source/drain region 109b, respectively. After that, as shown in FIG. 2C, the remaining unreacted metal film is removed. Note that, the silicide region 116 of the gate electrode 104 may not occupy a part of the gate electrode 104, but may occupy all the gate electrode 104 (Fully Silicided Gate).

Next, a contact etch stop film 118 made of, for example, Si₃N₄, and an interlayer insulating film 119 made of, for example, SiO₂ are successively deposited over the whole surface on the semiconductor substrate 101, and a surface of the interlayer insulating film 119 is then flattened by utilizing the CMP method or the like. Thereafter, the contact etch stop layer 118 and the interlayer insulating film 119 are patterned to form a contact hole, and a metal such as W is then sputtered. As a result, there is obtained a semiconductor device 100, as shown in FIG. 2D, having the contact 120, a wiring layer (not shown) and the like.

According to the second embodiment of the present invention, the existence of the third gate sidewall insulating film 202 makes it possible to reduce the relative dielectric constant of the whole gate sidewall insulating films. As a result, the parasitic capacitance can be further reduced in the second embodiment than in the first embodiment.

It should be noted that each of the above-mentioned first and second embodiments is merely an embodiment, the present invention is not intended to be limited thereto, and the various changes can be implemented without departing from the gist of the invention. For example, although the material for the first gate sidewall insulating film 114 in each of the first and second embodiments has been described by giving SiO₂ as an example, the material for the first gate sidewall insulating film 114 is not limited to SiO₂ as long as it has a lower relative dielectric constant than that of the material of the second gate sidewall insulating film 115. In addition, the gate sidewall insulating films may have a multi-layer structure including four or more layers.

In addition, the constituent elements of each of the above-mentioned first and second embodiments can be arbitrarily combined with each other without departing from the gist of the present invention.

What is claimed is:

1. A semiconductor device, comprising:
a semiconductor substrate;
a gate electrode formed on the semiconductor substrate through a gate insulating film;
an elevated source/drain region formed away from the gate electrode, a surface of the elevated source/drain region being higher than that of the semiconductor substrate;
a source/drain extension region formed in the semiconductor substrate lying under a recess portion formed between the gate electrode and the elevated source/drain region;
a first gate sidewall insulating film formed on a side face of the gate electrode, and on a bottom face and a side face of the recess portion; and
a second gate sidewall insulating film formed on the first gate sidewall insulating film.

2. A semiconductor device according to claim 1, wherein the second gate sidewall insulating film comprises a material showing a high etching selectivity to an oxide film.

3. A semiconductor device according to claim 1, wherein the first gate sidewall insulating film has a relative dielectric constant lower than that of the second gate sidewall insulating film.

4. A semiconductor device according to claim 1, wherein the first gate sidewall insulating film comprises silicon oxide and the second gate sidewall insulating film comprises silicon nitride.

5. A semiconductor device according to claim 1, further comprising a third gate sidewall insulating film formed on a surface of a part of the second gate sidewall insulating film, the third gate sidewall insulating film comprising a relative dielectric constant lower than that of the second gate sidewall insulating film.

6. A semiconductor device according to claim 5, wherein the first gate sidewall insulating film and the third gate sidewall insulating film comprise the same material.

7. A semiconductor device according to claim 5, wherein each of the first gate sidewall insulating film and the third gate sidewall insulating film comprises silicon oxide and the second gate sidewall insulating film comprises silicon nitride.

8. A semiconductor device according to claim 1, wherein the elevated source/drain region comprises silicon or silicon germanium.

9. A semiconductor device according to claim 8, wherein a source/drain silicide region is formed in a vicinity of a surface of the elevated source/drain region.

10. A semiconductor device according to claim 9, wherein the source/drain silicide region comprises at least any one of Ni, Pt, Co, Pd or Er.

11. A semiconductor device according to claim 9, wherein a gate silicide region is formed in a vicinity of a surface of the gate electrode.

12. A semiconductor device according to claim 11, wherein the gate silicide region comprises at least any one of Ni, Pt, Co, Pd or Er.

13. A semiconductor device according to claim 9, wherein the gate electrode is a fully silicide gate.

14. A semiconductor device according to claim 13, wherein the gate electrode comprises at least any one of Ni, Pt, Co, Pd or Er.

15. A method of fabricating a semiconductor device, comprising:
forming a gate electrode and a dummy gate sidewall insulating film above a semiconductor substrate;
forming an elevated source/drain region comprising silicon or a silicon compound in an exposed area of a surface of the semiconductor substrate after forming the gate electrode and the dummy gate sidewall insulating film above the semiconductor substrate;
removing the dummy gate sidewall insulating film; and
forming a plurality of insulating films comprising two or more different kinds of materials on the semiconductor substrate, and patterning the plurality of insulating films to form a gate sidewall insulating film comprising a multiple layer structure in a portion where the dummy gate sidewall insulating film has been removed.

16. A method of fabricating a semiconductor device according to claim 15, wherein the gate sidewall insulating film comprises a multiple layer structure comprising silicon oxide and silicon nitride formed on the silicin oxide.

17. A method of fabricating a semiconductor device according to claim 15, further comprising:
forming a metal film on a surface of the elevated source/drain region; and
causing the elevated source/drain region and the metal film to react with each other by performing a heat treatment to form a silicide region in a vicinity of a surface of the elevated source/drain region.

18. A method of fabricating a semiconductor device according to claim 17, wherein the metal film comprises at least any one of Ni, Pt, Co, Pd or Er.

19. A method of fabricating a semiconductor device according to claim 17, further comprising:
forming the metal film on a surface of an upper portion of the gate electrode; and
causing the gate electrode and the metal film to react with each other by performing the heat treatment to form a silicide region at least in a vicinity of the surface of the upper portion of the gate electrode.

20. A method of fabricating a semiconductor device according to claim 19, wherein the metal film comprises at least any one of Ni, Pt, Co, Pd or Er.
